(19) United States
(12) Patent Application Publication
(10) Pub. No.: US 2008/0067569 A1
(43) Pub. Date: Mar. 20, 2008

(54) MEMORY DEVICE WITH VERTICAL TRANSISTOR AND FABRICATION METHOD THEREOF

(75) Inventors: Sheng-Tsung Chen, Tainan City (TW); Shiah-Jyh Lin, Taipei County (TW); Chung-Yuan Lee, Taoyuan City (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/751,572

(22) Filed: May 21, 2007

(30) Foreign Application Priority Data
Sep. 20, 2006 (TW) TW95134789

(51) Int. Cl. H01L 27/108; H01L 21/8242

(52) U.S. Cl. 257/302; 438/245; 257/E21.646; 257/E27.084

(57) ABSTRACT

A method for fabricating a vertical transistor. At least one deep trench is formed in a silicon substrate. A conductive structure and a trench top insulator are successively formed in the deep trench, in which the conductive structure comprises a first doping region and the trench top insulator is below the surface of the silicon substrate. An epitaxial silicon layer is formed on the surface of the silicon substrate. Ion implantation is performed in the epitaxial silicon layer to form a second doping region therein. A gate structure is formed on the trench top insulator, protruding from the surface of the epitaxial silicon layer and adjacent to the sidewalls of the epitaxial silicon layer and the deep trench. A capping layer is formed on the epitaxial silicon layer. The invention also discloses a memory device with a vertical transistor and a method for fabricating the same.

### BACKGROUND OF THE INVENTION

1. Field of the Invention

The invention relates to memory devices and in particular to a memory device with a vertical transistor and a fabrication method thereof.

2. Description of the Related Art

In the rapidly evolving integrated circuit industry there is a development tendency toward high performance, miniaturization, and high operating speed. Additionally dynamic random access memory (DRAM) fabrication methods have developed rapidly. In particular, increase of large memory capacity is important for DRAMs.

Typically, current DRAM cells include a transistor and a capacitor. Since the capacity of current DRAM has reached 256 MB and up to 512 MB, the size of memory cells and transistors has narrowed to meet demands for high integration, higher memory capacity and higher operating speeds. In conventional planar transistor technology, however, more useable surface area on a chip is required, and it is difficult to meet the previously mentioned demands. Accordingly, vertical transistor technology has been applied to DRAM fabrication with the goal of reducing the area occupied by the transistor and the capacitor on the semiconductor substrate. The conventional planar transistor technology requires a large surface area on the chip, and cannot accomplish the demand for high integration. Conversely, vertical transistor technology can improve upon the disadvantages of the conventional semiconductor memory cell, and is positioned to become a major semiconductor memory cell fabrication method.

Generally, in the fabrication of vertical transistors, channel length depends on deep trench depth and depth for etching back a conductive gate material formed in the deep trench. As the size of devices is reduced, it is difficult to control the channel length by etching back a conductive gate material formed in the deep trench.

Thus, there exists a need in the art for a method for fabricating a memory device with a vertical transistor to effectively control the channel length of vertical transistor.

### BRIEF SUMMARY OF THE INVENTION

A detailed description is given in the following embodiments with reference to the accompanying drawings. A memory device with a vertical transistor and methods for fabricating the vertical transistor and the memory device are provided. An embodiment of a method for fabricating a vertical transistor comprises forming at least one deep trench in a silicon substrate. A conductive structure and a trench top insulator are successively formed in the deep trench, in which the conductive structure comprises a first doping region and the trench top insulator is below the surface of the silicon substrate. An epitaxial layer is formed on the surface of the silicon substrate. Ion implantation is performed in the epitaxial silicon layer to form a second doping region therein. A gate structure is formed on the trench top insulator, protruding from the surface of the epitaxial silicon layer and adjacent to the sidewalls of the epitaxial silicon layer and the deep trench. A capping layer is formed on the epitaxial silicon layer.

An embodiment of a method for fabricating a memory device with a vertical transistor comprises forming a hard mask pattern layer on a silicon substrate. At least one deep trench is formed in the silicon substrate using the hard mask pattern layer as an etch mask. A trench capacitor is formed in the deep trench. A conductive structure and a trench top insulator are successively formed on the trench capacitor in the deep trench, wherein the conductive structure comprises a first doping region and the trench top insulator is below the surface of the silicon substrate. The hard mask pattern layer is removed to expose the surface of the silicon substrate. An epitaxial silicon layer is formed on the surface of an exposed silicon substrate. Ion implantation is performed in the epitaxial silicon layer to form a second doping region therein. A gate structure is formed on the trench top insulator, protruding from the surface of the epitaxial silicon layer and adjacent to the sidewalls of the epitaxial silicon layer and the deep trench. A capping layer is formed on the epitaxial silicon layer

An embodiment of a memory device with a vertical transistor comprises a substrate having at least one deep trench therein. A trench capacitor is disposed in the deep trench. A conductive structure is disposed on the trench capacitor in the deep trench, comprising a first doping region. A trench top insulator is disposed on the conductive structure in the deep trench and below the surface of the silicon substrate. An epitaxial silicon layer is disposed on the surface, comprising a second doping region therein. A gate structure is disposed on the trench top insulator, protruding from the surface of the epitaxial silicon layer and adjacent to the sidewalls of the epitaxial silicon layer and the deep trench. A capping layer is disposed on the epitaxial silicon layer.

### BRIEF DESCRIPTION OF DRAWINGS

The invention can be more fully understood by reading the subsequent detailed description and examples with references made to the accompanying drawings, wherein:

FIG. 1 is a plan view of an embodiment of a memory device with vertical transistors;

FIGS. 2A to 2F are cross sections of an embodiment of a method for fabricating a memory device along line 2-2′ shown in FIG. 1; and

FIGS. 3A to 3F are cross sections of an embodiment of a method for fabricating a memory device along line 3-3′ shown in FIG. 1.

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims. The memory device with a vertical transistor of this invention will be described below with reference to the accompanying drawings.

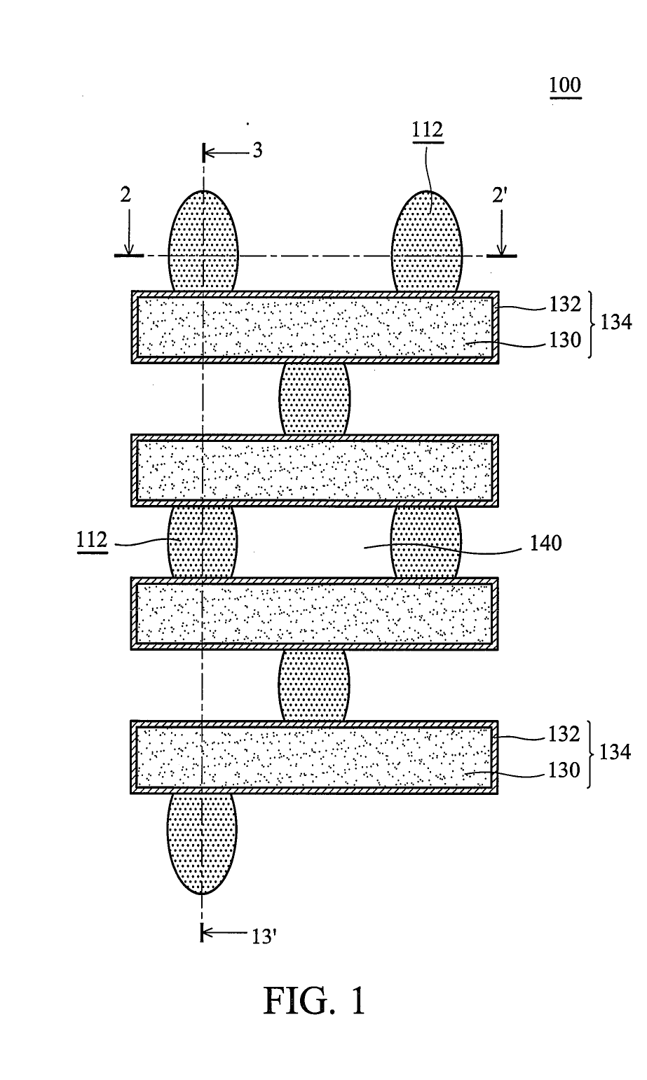

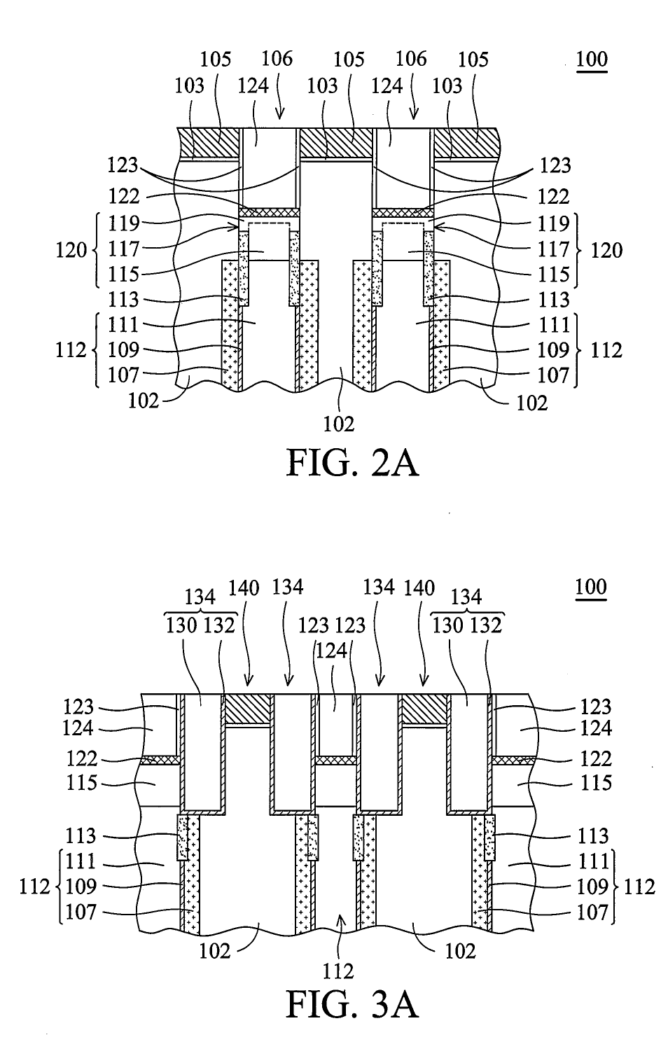

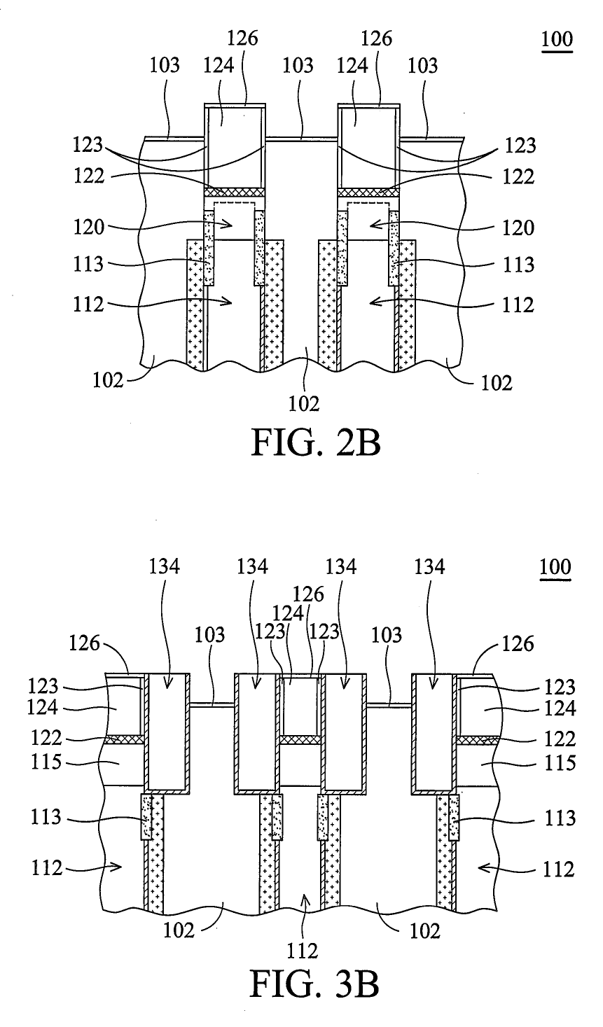

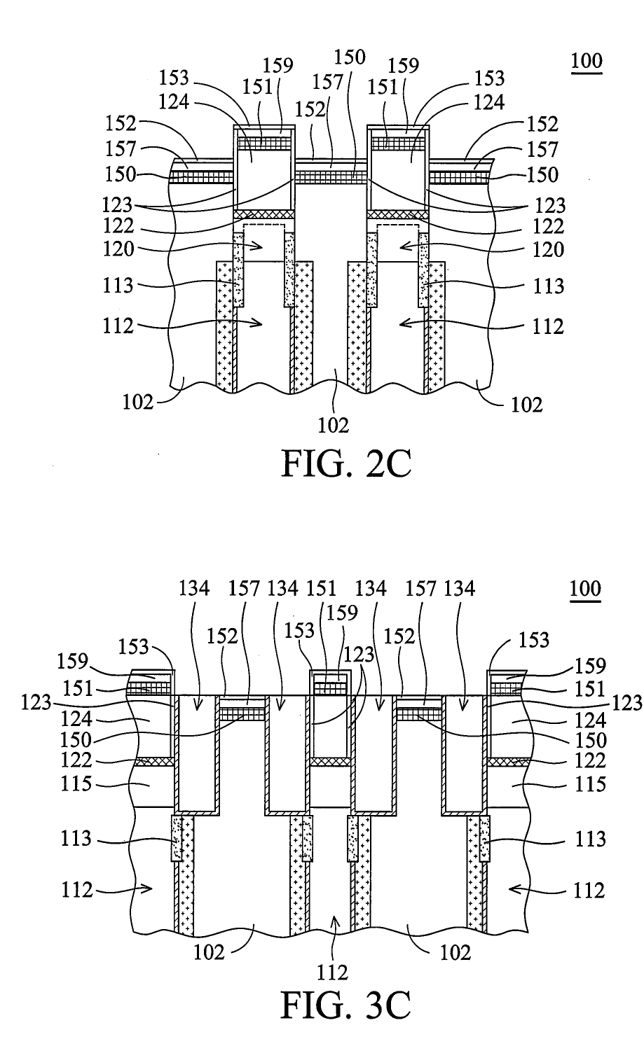

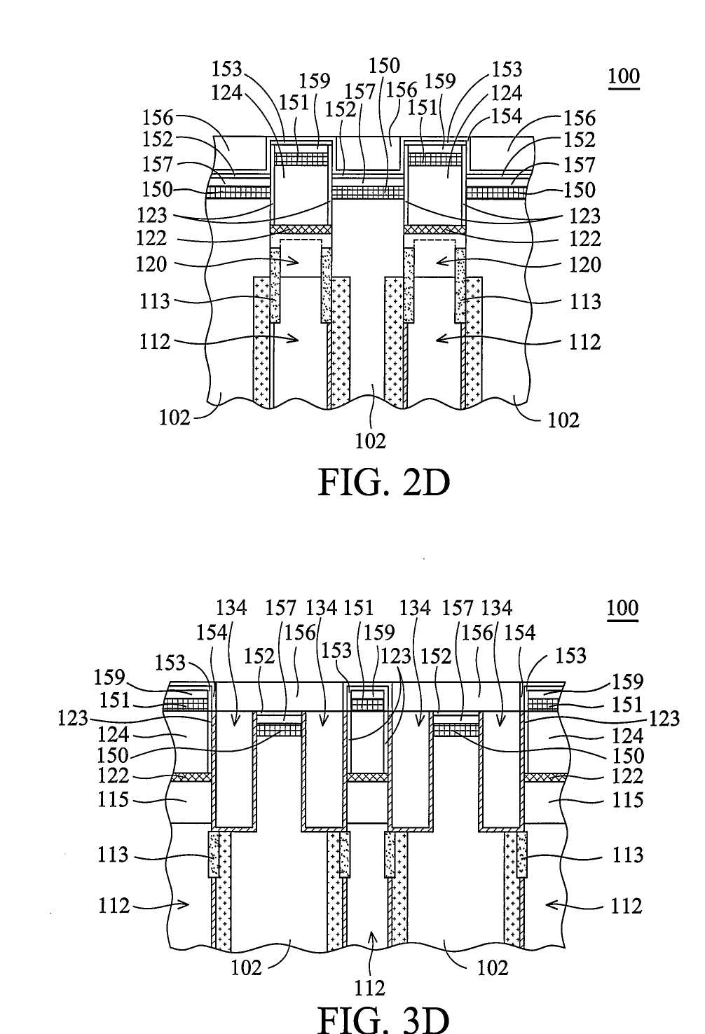

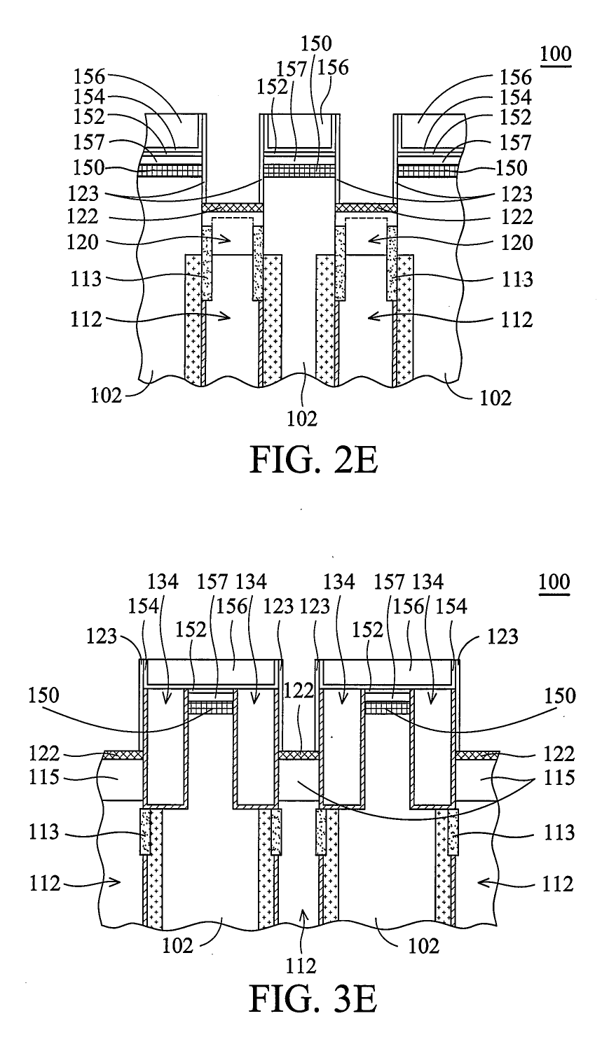

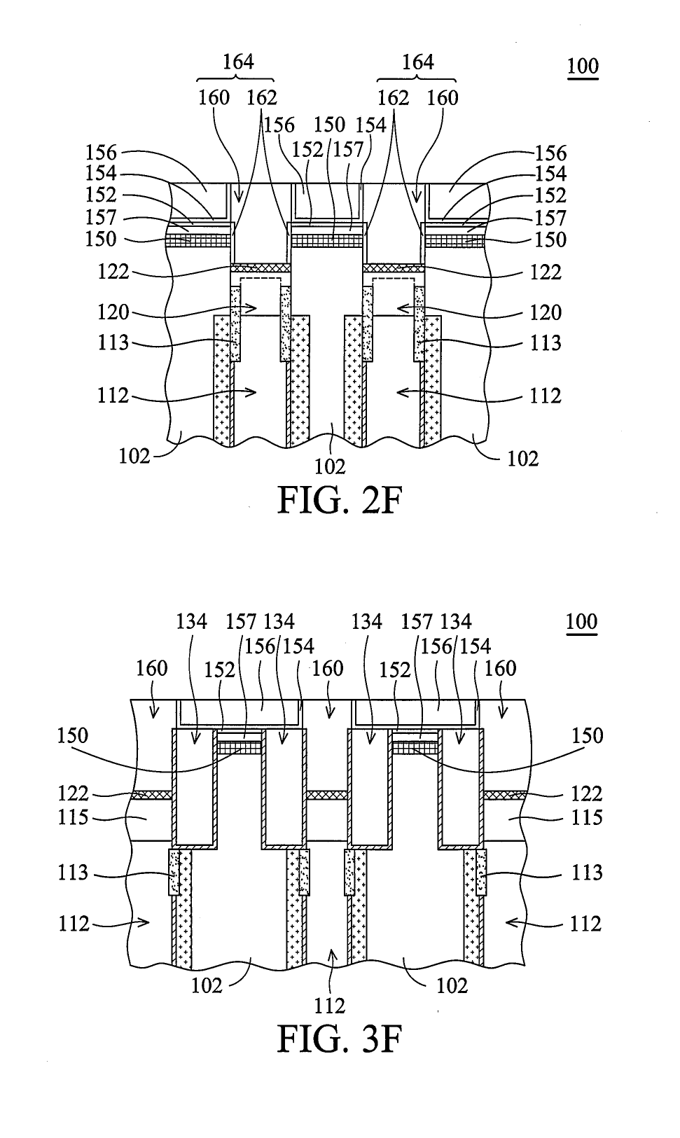

The invention relates to a memory device with a vertical transistor and a method for fabricating the same. FIG. 1 is a plan view of an embodiment of memory devices 100 with vertical transistors. FIGS. 2A to 2F are cross sections of an embodiment of a method for fabricating a memory device 100 along line 2-2′ shown in FIG. 1, and FIGS. 3A to 3F are cross sections of an embodiment of a method for fabricating a memory device 100 along line 3-3′ shown in FIG. 1. As shown in FIG. 1, the memory device 100 comprises deep trench capacitors 112, shallow trench isolation (STI) structures 134 and active areas 140.

FIG. 2F is a cross section of a memory device 100 with a vertical transistor. The memory device 100 comprises a silicon substrate 102 having deep trenches 106 (as shown in FIG. 2A). Trench capacitors 112 are respectively disposed in each deep trench 106. A conductive structure 120 is disposed on the trench capacitor 112 in the deep trench 106. The conductive structure 120 comprises a conductive layer 115, such as a polysilicon layer, and a buried strap (BS) 117. The buried strap 117 is disposed on the conductive layer 115 and surrounds the upper portion of the conductive layer 115, in which a first doping region 119 is formed in the buried strap 117, as shown in FIG. 2A. A trench top insulator 122, such as a silicon oxide layer, is disposed on the conductive structure 120 in the deep trench 106 and is below the surface of the silicon substrate 102. An epitaxial silicon layer 150 is disposed on the surface of the silicon substrate 102, having a second doping region 157 therein. A gate structure 164 is disposed on the trench top insulator 122, protruding from the surface of the epitaxial silicon layer 150 and adjacent to the sidewalls of the epitaxial silicon layer 150 and deep trench 106. A capping layer 156, such as a silicon oxide layer, is disposed on the epitaxial silicon layer 150.

As shown in FIGS. 2A and 3A, a silicon substrate 102, such as a silicon wafer, is provided. A hard mask layer (not shown) comprising a pad oxide layer and a silicon nitride layer is formed on the silicon substrate 102. Next, a hard mask pattern layer comprising a patterned pad oxide layer 103 and a patterned silicon nitride layer 105 is formed by lithography and etching to expose silicon substrate 102. An exposed silicon substrate 102 is etched using the patterned silicon nitride layer 105 as a hard mask to form deep trenches 106. A trench capacitor 112 may be formed in each deep trench 106 by conventional methods. The trench capacitor 112 typically comprises a top electrode 111 comprising polysilicon, a capacitor dielectric layer 109 and a bottom electrode 107 formed in the substrate 102 around the lower portion of the deep trench 106.

After the trench capacitor 112 is completed, a collar dielectric layer 113, such as a collar oxide layer, is formed on the sidewall of the deep trench 106 above the trench capacitor 112. A conductive structure 120 is subsequently formed on the trench capacitor 112 in the deep trench 106, in which a portion of the conductive structure 120 is surrounded by the collar dielectric layer 113. In this embodiment, the conductive structure 120 may comprise a conductive layer 115, such as a polysilicon layer, and a buried strap (BS) 117. The conductive layer 115 is electrically connected to the trench capacitor 112. The buried strap 117 is formed on the conductive layer 115 and surrounds the upper portion thereof, in which a first doping region 119 is formed in the buried strap 117 to electrically connect a transistor (not shown) thereabove. In some embodiments, a thin buried strap nitridation layer (not shown) may be formed on the sidewall of the deep trench 106 above the collar dielectric layer 113 to control current or ion diffusion.

A trench top insulator 122, such as a trench top oxide (TTO) is formed on the conductive structure 120 and below the surface of the silicon substrate 102. In some embodiments, the trench top insulator 122 can be formed by filling the deep trench 106 with silicon oxide using high density plasma chemical vapor deposition (HDPCVD). Thereafter, the excess silicon oxide on the patterned silicon nitride layer 105 is removed by wet etching and the trench top insulator 122 is complete.

Shallow trench isolation structures 134 are formed to define active areas 140. In this embodiment, a silicon oxide layer 123 is formed on the sidewalls of the hard mask pattern layer (i.e. the patterned pad oxide layer 103 and the patterned silicon nitride layer 105) and the deep trench 106. A polysilicon layer 124 is subsequently filled in the deep trench 106. A hard mask pattern layer (not shown), such as a boron-silicate glass (BSG) layer and an overlying polysilicon layer, is formed on the silicon substrate 102 to define shallow trench isolation areas and active areas 140. The hard mask pattern layer (not shown) is removed after definition of the shallow trench isolation areas and active areas 140. Next, shallow trench isolation structures 134 are formed in the shallow trench isolation areas, in which each shallow trench isolation structure comprises a silicon nitride liner 132 and a silicon oxide layer 130 formed by HDPCVD.

As shown in FIGS. 2B and 3B, the patterned silicon nitride layer 105 shown in FIGS. 2A and 3A can be removed by wet etching to expose the patterned pad oxide layer 103 and a portion of polysilicon layer 124. The exposed polysilicon layer 124 is subsequently oxidized to form a silicon oxide layer 126 thereon.

As shown in FIGS. 2C and 3C, the patterned pad oxide layer 103 and the silicon oxide layer 126 on the polysilicon layer 124 shown in FIGS. 2B and 3C can be removed by anisotropic etching to expose the surfaces of the polysilicon layer 124 and the silicon substrate 102. Selective epitaxial silicon layers 151 and 150 are respectively formed on the surfaces of the polysilicon layer 124 and silicon substrate 102. The epitaxial silicon layers 151 and 150 are oxidized by thermal oxidation to form silicon oxide layers 153 and 152 thereon. Ion implantation is subsequently performed to form second doping regions 159 and 157 in the epitaxial silicon layers 151 and 150, respectively. In this embodiment, the epitaxial silicon layer 150 is located between the first doping region 119 in the buried strap 117, as shown in FIG. 2A, and the second doping region 157 to serve as source/drain regions where a channel region (not shown) is defined therebetween and has a channel length determined by the thickness of the epitaxial silicon layer 150.

As shown in FIGS. 2D and 3D, insulators are formed on the epitaxial silicon layer 150 to protect the epitaxial silicon layer 150 in subsequent processes. For example, a silicon nitride liner 154 is formed on the surface of the structure shown in FIGS. 2C and 3C. A blanket insulating layer (not shown) is deposited on the silicon nitride liner 154. Next, planarization is performed by, for example, chemical mechanical polishing (CMP), to form capping layers 156 on the silicon oxide layer 152 and the shallow trench isolation structures 134.

As shown in FIGS. 2E and 3E, the silicon nitride liner 154 on the silicon oxide layer 153 shown in FIGS. 2D and 3D is removed to expose the silicon oxide layer 153. The exposed silicon oxide layer 153 and the underlying epitaxial silicon layer 151 and polysilicon layer 124 are successively removed by, for example, wet etching or dry etching, to expose the trench top insulator 122.

As shown in FIGS. 2F and 3F, the silicon oxide layer 123 on the sidewall of the deep trench 106 shown in FIGS. 2D and 2E is removed by wet etching. Next, a gate structure 164 is formed on the trench top insulator 122 in the deep trench 106. For example, a gate dielectric layer 162, such as a silicon oxide layer, is formed on the sidewalls of the epitaxial silicon layer 150 and the deep trench 106. In some embodiments, the gate dielectric layer 162 may comprise other materials. Next, a conductive layer, such as a polysilicon layer, is formed on the trench top insulator 122 in the deep trench 106 to form a gate electrode 160. Thus, the formation of a vertical transistor is complete. The gate electrode 160 is adjacent to the gate dielectric layer 162 and protrudes the surface of the epitaxial silicon layer 150.

According to the invention, the channel length of the vertical transistor is determined by the deposition thickness of the epitaxial silicon layer and can be controlled more effectively compared to the conventional method by back etching a conductive material. Moreover, since the active area of the memory device is defined prior to formation of the gate electrode of the vertical transistor, the gate dielectric layer of the vertical transistor is protected from damage, thereby increasing device reliability.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a vertical transistor, comprising:
forming at least one deep trench in a silicon substrate;
successively forming a conductive structure and a trench top insulator in the deep trench, wherein the conductive structure comprises a first doping region and the trench top insulator is below the surface of the silicon substrate;
forming an epitaxial silicon layer on the surface of the silicon substrate;
performing ion implantation in the epitaxial silicon layer to form a second doping region therein;
forming a gate structure on the trench top insulator, protruding from the surface of the epitaxial silicon layer and adjacent to the sidewalls of the epitaxial silicon layer and the deep trench; and
forming a capping layer on the epitaxial silicon layer.

2. The method as claimed in claim 1, wherein formation of the conductive structure comprises:
forming a conductive layer in the deep trench; and
forming a buried strap on the conductive layer and surrounding the upper portion thereof, wherein the first doping region is in the buried strap.

3. The method as claimed in claim 1, wherein the trench top insulator is formed by silicon oxide using high density plasma chemical vapor deposition (HDPCVD).

4. The method as claimed in claim 1, wherein formation of the gate structure comprises:
forming a gate dielectric layer on the sidewalls of the epitaxial silicon layer and the deep trench by thermal oxidation; and
forming a conductive layer on the trench top insulator and protruding from the surface of the epitaxial silicon layer to serve as a gate electrode.

5. The method as claimed in claim 4, wherein the conductive layer comprises polysilicon.

6. A method for fabricating a memory device with a vertical transistor, comprising:
forming a hard mask pattern layer on a silicon substrate;
forming at least one deep trench in the silicon substrate using the hard mask pattern layer as an etch mask;
forming a trench capacitor in the deep trench;
successively forming a conductive structure and a trench top insulator on the trench capacitor in the deep trench, wherein the conductive structure comprises a first doping region and the trench top insulator is below the surface of the silicon substrate;
removing the hard mask pattern layer to expose the surface of the silicon substrate;
forming an epitaxial silicon layer on the surface of an exposed silicon substrate;
performing ion implantation in the epitaxial silicon layer to form a second doping region therein;
forming a gate structure on the trench top insulator, protruding from the surface of the epitaxial silicon layer and adjacent to the sidewalls of the epitaxial silicon layer and the deep trench; and
forming a capping layer on the epitaxial silicon layer.

7. The method as claimed in claim 6, wherein the hard mask pattern layer comprises a pad oxide layer and a silicon nitride layer.

8. The method as claimed in claim 6, wherein formation of the conductive structure comprises:
forming a conductive layer in the deep trench; and
forming a buried strap on the conductive layer and surrounding the upper portion thereof, wherein the first doping region is in the buried strap.

9. The method as claimed in claim 6, wherein the trench top insulator is formed by silicon oxide using high density plasma chemical vapor deposition (HDPCVD).

10. The method as claimed in claim 6, wherein formation of the gate structure comprises:
forming a gate dielectric layer on the sidewalls of the epitaxial silicon layer and the deep trench by thermal oxidation; and
forming a conductive layer on the trench top insulator, adjacent to the gate dielectric layer and protruding from the surface of the epitaxial silicon layer to serve as a gate electrode.

11. The method as claimed in claim 10, wherein the conductive layer comprises polysilicon.

12. A memory device with a vertical transistor, comprising:
a substrate having at least one deep trench therein;
a trench capacitor disposed in the deep trench;
a conductive structure disposed on the trench capacitor in the deep trench, comprising a first doping region;
a trench top insulator on the conductive structure in the deep trench and below the surface of the silicon substrate;
an epitaxial silicon layer disposed on the surface of the silicon substrate, comprising a second doping region therein;
a gate structure disposed on the trench top insulator, protruding from the surface of the epitaxial silicon layer and adjacent to the sidewalls of the epitaxial silicon layer and the deep trench; and
a capping layer disposed on the epitaxial silicon layer.

13. The memory device as claimed in claim 12, wherein the conductive structure comprises:
a conductive layer; and
a buried strap disposed on the conductive layer and surrounding the upper portion thereof, wherein the first doping region is in the buried strap.

14. The memory device as claimed in claim 13, wherein the conductive layer comprises polysilicon.

15. The memory device as claimed in claim 12, wherein the trench top insulator comprises silicon oxide.

16. The memory device as claimed in claim 12, wherein the capping layer comprises silicon oxide.
